(19) United States
(12) Patent Application Publication
(10) Pub. No.: US 2002/0146053 A1
(43) Pub. Date: Oct. 10, 2002

(54) Surface emitting semiconductor laser device

(76) Inventor: Norihiro Iwai, Tokyo (JP)

Correspondence Address: KNOBBE MARTENS OLSON & BEAR LLP, 620 NEWPORT CENTER DRIVE, SIXTEENTH FLOOR, NEWPORT BEACH, CA, 92660, US

(21) Appl. No.: 10/012,254

(22) Filed: Nov. 8, 2001

(30) Foreign Application Priority Data
Apr. 5, 2001 (JP) 2001-106884

(51) Int. Cl. H01S 5/00; H01S 3/091; H01S 3/094

(52) U.S. Cl. 372/75; 372/50

(57) ABSTRACT

A surface emitting semiconductor laser device includes a GaAs substrate, and first and second laser sections consecutively and monolithically formed on the GaAs substrate. The second laser section has an active layer structure having a bandgap wavelength longer than the bandgap wavelength of the active layer structure of the first laser section. The second laser section is pumped by a first laser emitted by the first laser section to emit second laser.

### BACKGROUND OF THE INVENTION

1. Field of the Invention

The present invention relates to a long-wavelength surface emitting semiconductor laser device and, more particularly, to a long-wavelength surface emitting semiconductor laser device having a higher emission efficiency, an improved temperature characteristic and a longer lifetime.

2. Description of the Related Art

A surface emitting semiconductor laser device (hereinafter referred to as simply “surface emitting laser”) emits laser in the direction perpendicular to the main surface of the substrate and has an advantage over the conventional Fabry-Perot laser device in that a plurality of semiconductor laser devices can be arranged on a single substrate in a two-dimensional array. Thus, the surface emitting laser attracts a larger attention in the field of data communication in these days.

The surface emitting laser includes a GaAs or InP substrate, a pair of multilayer reflecting mirrors (hereinafter referred to as DBR mirrors) each including a plurality of, for example, AlGaAs/AlGaAs (different Al contents) layer pairs and a laser active layer structure sandwiched between the DBR mirrors for emission of laser.

There have been some proposals on the current confinement structure of the surface emitting laser using an Al-oxidized area for achieving a low threshold current and a higher emission efficiency.

Among the long-wavelength surface emitting lasers, a GaInNAs-based surface emitting laser, which includes GaInNAs-based compound semiconductor materials for the active layer, is especially highlighted. This is because the GaInNAs-based surface emitting laser can be formed by an epitaxial process on a GaAs substrate, on which Al(Ga)As-based DBR mirrors having a higher thermal conductivity and a higher reflection factor can be grown, whereby the GaInNAs-based surface emitting laser emits laser having a wavelength as long as 1.2 to 1.6 μm.

With reference to FIG. 1, a conventional GaInNAs-based surface emitting laser 10 includes an n-GaAs substrate 12, and a layer structure formed thereon by an epitaxial process. The layer structure includes, consecutively as viewed from the bottom, a lower DBR mirror 14 including a plurality (35 in this example) of n-Al_{0.9}GaAs/n-GaAs layer pairs, a lower cladding layer 16, a quantum well (QW) active layer structure 18, an upper cladding layer 20, and an upper DBR mirror 22 including a plurality (25 in this example) of p-Al_{0.9}GaAs/p-GaAs layer pairs. Each layer of the DBR mirrors has a thickness corresponding to λ/4n, wherein λ and n are emission wavelength of the laser and the refractive index of the each layer, respectively.

In the upper DBR mirror 22, one of the p-Al_{0.9}GaAs layers disposed in the vicinity of the active layer structure 18 is replaced by a p-AlAs layer 24 having an Al-oxidized area 24A and an Al-non-oxidized area 24B. The Al-oxidized area 24A is formed by selectively oxidizing the p-AlAs layer 24 to obtain a current confinement structure.

The QW active layer structure 18 includes GaInNAs/GaAs layers, wherein the GaInNAs well layer is implemented by a Ga_{0.63}In_{0.37}N_{0.01}A_{0.99} layer having a compressive strain of 2.5% and a thickness of 8 nm, and each of the GaAs barrier layers has a thickness of 10 nm.

The upper DBR mirror 22 including the p-AlAs layer 24 is configured to form a cylindrical mesa post having a diameter of about 30 μm by using photolithography and an etching process.

The p-AlAs layer 24 in the mesa post is thermally treated in a steam ambient for oxidation at a temperature of about 400 degrees C., whereby the annular peripheral area of the p-AlAs layer 24 is selectively oxidized to form the Al-oxidized area 24A. For example, the annular Al-oxidized area 24A has a width of 10 μm, and the central Al-non-oxidized area or aperture area 24B has an area of about 80 μm² or a diameter of 10 μm.

The mesa post is buried by a polyimide burying layer 26 at the side-wall of the mesa post. An annular p-side electrode 28 having an outer diameter of 5 to 10 μm is formed on the top of the mesa post, whereas an n-side electrode 30 is formed on the bottom surface of the n-GaAs substrate 12, after the n-GaAs substrate 12 is ground to have a thickness of about 200 μm. On the polyimide layer 26, an electrode pad 32 is disposed in contact with the outer periphery of the annular electrode 28.

The GaInNAs-based semiconductor materials, which can be grown on a GaAs substrate as described above, are conveniently used for achieving a long-wavelength surface emitting laser by utilizing the conventional technique for forming an existing 850-nm surface emitting laser.

It is known that the surface emitting laser having the GaInNAs-based semiconductor materials and a longer emission wavelength can be realized by increasing the indium (In) content in GaInNAs. However, in the current technique, the maximum In content is limited to around 30 to 40%, and achieves an emission wavelength of 1.1 to 1.25 μm, which is below a desired emission wavelength.

A surface emitting laser has been long desired, which lases at a longer wavelength of 1.2 to 1.6 μm and has a higher emission efficiency, an improved temperature characteristic and a longer lifetime.

In this respect, it is also known that a larger nitrogen (N) content in GaInNAs also increases the emission wavelength of the surface emitting laser. An emission wavelength above 1.2 μm can be realized by controlling the nitrogen content in the GaInNAs, and for example, 1.3-μm surface emitting laser can be generally obtained by a nitrogen content of 0.5 to 1% in the GaInNAs-based materials. A 1.55-μm surface emitting laser may be also obtained by a nitrogen content of about 5% in the GaInNAs-based materials

The nitrogen content as high as 0.5 to 1%, however, has a disadvantage in that the peak intensity of the photoluminescence (PL intensity) is lowered. For example, a nitrogen content equal to about 0.5% lowers the PL intensity by 1/100 compared to the case of no nitrogen content. This is considered due to degradation of crystallinity of the layer by the introduction of nitrogen.

The degradation of the crystallinity caused by the larger nitrogen content lowers the quantum effect. For example, in a surface emitting laser having a pair of Al_{0.9}GaAs/GaAs DBR mirrors, a hetero-spike occurring at the interface between the Al_{0.9}GaAs layer and the GaAs layer raises the operational voltage of the laser. The rise of the operational voltage may be suppressed by doping the layers with impurities at a dosage of 1 ×10¹⁸ to 5×10¹⁸ cm⁻³, which however significantly lowers the quantum efficiency due to absorption of free carriers by the impurities and thus reduces the optical output of the surface emitting laser.

As described above, it is generally difficult to fabricate a surface emitting laser having a longer emission wavelength of 1.2 to 1.6 μm, with a higher emission efficiency, an improved temperature characteristic and a longer lifetime.

In another approach to a long-wavelength surface emitting laser, Patent Publication JP-A-10-501927 based on a PCT application describes a combination of a short-wavelength vertical-cavity surface emitting laser (VCSEL) and a long-wavelength VCSEL pumped by the short-wavelength VCSEL.

Referring to FIG. 2, the combination laser described in the above publication includes the short-wavelength VCSEL 41 having an emission wavelength of 980 nm, and the longs wavelength VCSEL 42 having an emission wavelength above 980 nm and pumped by the short-wavelength VCSEL 41.

The long-wavelength VCSEL 42 includes a GaAs substrate 43, a lower DBR mirror 44 formed on the GaAs substrate 43 and having undoped GaAs/AlAs layer pairs, an active layer structure 45, and a dielectric upper mirror 46. The GaAs substrate 43 is coupled to a GaAs substrate 48 of the short-wavelength VCSEL 41 by using a transparent adhesive 47, a metallic coupling technique or a wafer bonding technique. Both VCSELs 41 and 42 have similar structures.

The described combination laser, however, has a lower throughput for fabrication thereof due to the bonding process for the substrates, and thus is not suited for mass production of the surface emitting laser.

### SUMMARY OF THE INVENTION

In view of the above, it is an object of the present invention to provide a GaInNAs-based surface emitting laser having a longer emission wavelength, with a higher emission efficiency, an improved temperature characteristic and a longer wavelength.

The present invention provides a surface emitting semiconductor laser device including: a GaAs substrate; a first laser section formed on the GaAs substrate and including a first active layer structure having a first bandgap wavelength; and a second laser section monolithically formed on the second laser section and including a second active layer structure having a second bandgap wavelength longer than the first bandgap wavelength, the second laser section being pumped by first laser emitted by the first laser section to emit second laser.

In accordance with the present invention, due to the combination laser structure monolithically formed on a single GaAs substrate, the surface emitting laser having an emission wavelength as long as 1.31 μm or longer, with higher emission efficiency, a superior temperature characteristic and a longer lifetime can be fabricated with a higher throughput and a lower cost.

The above and other objects, features and advantages of the present invention will be more apparent from the following description, referring to the accompanying drawings.

### BRIEF DESCRIPTION OF THE DRAWINGS

FIG. 1 is a sectional view of a conventional surface emitting laser.

FIG. 2 is a sectional view of a conventional combination laser described in a patent publication.

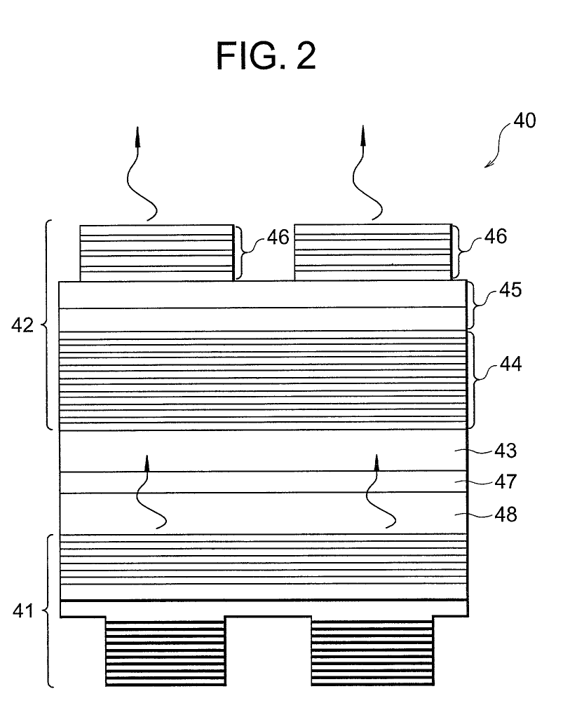

FIG. 3 is a sectional view of a surface emitting laser according to an embodiment of the present invention.

FIGS. 4A to 4D are sectional views of the surface emitting laser of FIG. 3, showing consecutive steps of fabrication thereof.

FIG. 5 is a graph showing the change rate of the optical output in the surface emitting laser of FIGS. 1 and 3 with respect to operational time thereof.

FIG. 6 is a graph showing the relationship between the injection current and the optical output of the surface emitting laser of FIGS. 1 and 3.

### PREFERRED EMBODIMENTS OF THE INVENTION

Now, the present invention is more specifically described with reference to accompanying drawings.

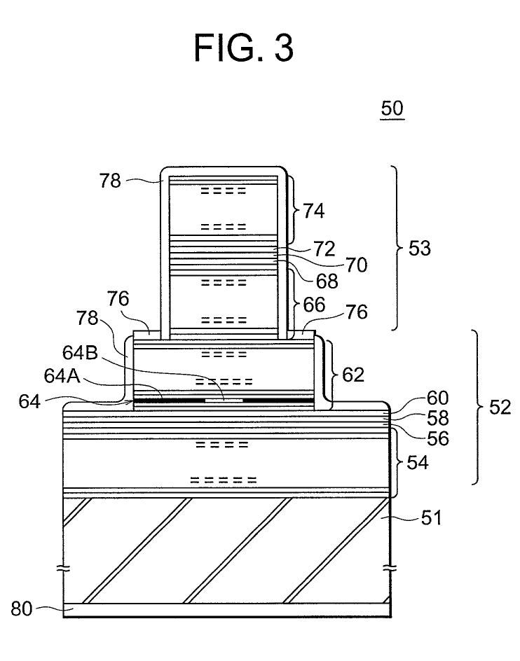

Referring to FIG. 3, a surface emitting laser according to an embodiment of the present invention is implemented as a combination laser including a pair of laser sections monolithically formed on a single GaAs substrate.

More specifically, the surface emitting laser of the present embodiment, generally designated by numeral 50, includes an n-type GaAs (n-GaAs) substrate 51, a first surface emitting laser section (first laser section) 52 formed on the n-GaAs substrate 51 and having an emission wavelength of 850 nm, and a second surface emitting laser section (second laser section) 53 formed on the first laser section 52 and having an emission wavelength of 1300 nm. The first laser section 52 has GaAs/AlGaAs-based layer structure, whereas the second laser section 53 includes a GaInNAs-based layer structure.

The first laser section 52 has a layer structure including, as viewed from the bottom, a lower DBR mirror 54 including a plurality (35 in this example) of n-Al_{0.9}GaAs/n-Al_{0.2}GaAs layer pairs, a lower cladding layer 56, a QW active layer structure 58, an upper cladding layer 60, and an upper DBR mirror 62 including a plurality (25 in this example) of p-Al_{0.9}GaAs/p-Al_{0.2}GaAs layer pairs. Each layer of the DBR mirrors 54 and 62 has a thickness corresponding to λ/4n, wherein λ and n are emission wavelength of the first laser section 52 and the refractive index of the each layer, respectively.

The lower DBR mirror 54 and the upper DBR mirror 62 of the first laser section 52 have respective thicknesses which allow these DBR mirrors 54 and 62 to function as reflecting mirrors for the laser of a wavelength of 850nm. The active layer structure 58 sandwiched therebetween is formed as a GaAs/Al_{0.2}GaAs QW structure having an emission wavelength of 850 nm.

In the upper DBR mirror 62, one of the n-Al_{0.9}GaAs layers is replaced by a p-AlAs layer 64 in the vicinity of the active layer structure 58. The Al content in the peripheral area of the p-AlAs layer 64 is selectively oxidized to form an Al-oxidized area 64A which constitutes a current confinement structure, with the remaining central area being left as an Al-non-oxidized area 64B which is used as a current injection area.

The most part of the upper DBR mirror 62 is configured to form a cylindrical, first mesa post having a diameter of 40 μm, with the remaining part of the upper DBR mirror 62 below the p-AlAs layer 64 being left as the original shape. The Al-oxidized area 64A has a width of 15 μm, whereas the Al-non-oxidized area 64B has an area of about 80 μm or a diameter of 10 μm.

The second laser section 53 has a layer structure formed on the upper DBR mirror 62 of the first laser section 52, the layer structure including a lower DBR mirror 66 having a plurality of (30 in this example) Al_{0.9}GaAs/un-doped Al_{0.2}GaAs layer pairs, a lower cladding layer 68, a GaInNAs-based QW active layer structure 70, an upper cladding layer 72, and an upper DBR mirror 74 having a plurality (25 in this example) of Al_{0.9}GaAs/un-doped Al_{0.2}GaAs layer pairs. Each layer of the DBR mirrors 66 and 74 has a thickness corresponding to λ/4n, wherein λ and n are emission wavelength of the second laser section 53 and the refractive index of the each layer.

The GaInNAs-based QW active layer structure 70 includes a pair of GaInNAs well layers and there GaAs barrier layers each two of which sandwiches therebetween one of the GaInNAs well layers. The GaInNAs well layer has a composition of Ga_{0.63}In_{0.37}N_{0.01}As_{0.99}, a thickness of 8 nm, and a compressive strain of 2.5%, whereas the GaAs barrier layer has a thickness of 10 nm. The GaInNAs-based QW active layer structure 70 lases at a wavelength of 1.3 μm. The lower DBR mirror 66 and the upper DBR mirror 74 have respective thicknesses which allow the DBR mirrors to function as reflecting mirrors for laser of 1300-nm-band wavelength.

The layer structure including the lower DBR mirror 66, the lower cladding layer 68, the GaInNAs-based QW active layer structure 70, the upper cladding layer 72, and the upper DBR mirror 74 is configured to form a cylindrical, second mesa post having a diameter of about 30 μm.

A p-side electrode 76 having a width of 5 to 10 μm is formed on the peripheral annular area of the top of the first mesa post. The layer structures of the first and second mesa posts are covered by a SiNx protective film 78 except for the p-side electrode 76. An n-side electrode 80 is formed on the bottom surface of the n-GaAs substrate 51, which is ground beforehand so that the n-GaAs substrate 51 has a thickness of 200 μm, for example.

In the surface emitting laser 50 of the present embodiment, the laser emitted by the first laser section 52 and having an emission wavelength of 850 nm pumps the GaInNAs-based QW active layer structure (or absorption region) of the second laser section 53, thereby allowing the second laser section 53 to emit laser having a wavelength of 1.3 μm.

In the surface emitting laser 50 of the present embodiment, the lifetime thereof is determined by the first laser section 52 because no exciting current is injected into the active QW structure of the second laser section 53. Thus, the surface emitting laser 50 of the present embodiment has the advantage of a longer lifetime over the conventional GaInNAs-based surface emitting laser.

In addition, the DBR mirrors 66 and 74 for reflecting 1.3-μm laser and sandwiching therebetween the GaInNAs-based QW active layer structure 70 can be made of undoped layers because no exciting current is injected from electrodes into the GaInNAs-based QW active layer structure 70. Thus, a free carrier absorption by impurities as encountered in the conventional surface emitting laser can be reduced, whereby improvement of an emission efficiency can be expected.

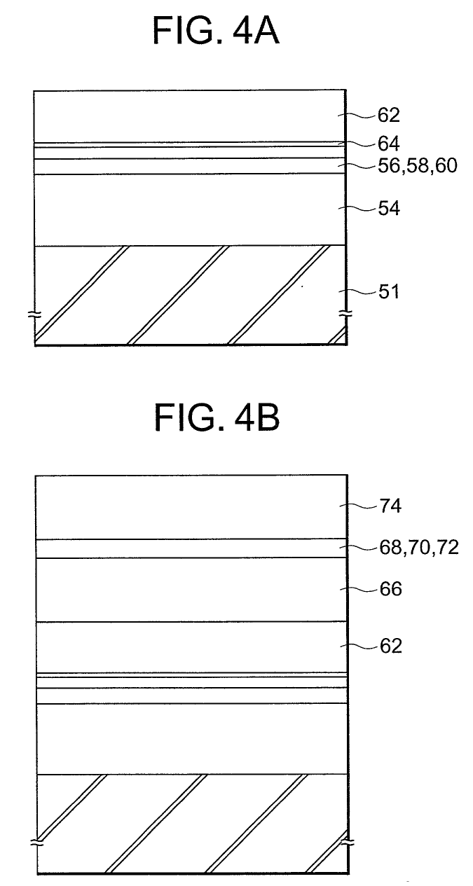

A fabrication process for the surface emitting laser of the present embodiment will be described with reference to FIGS. 4A to 4D. In FIG. 4A, the first laser section 52 including the lower DBR mirror 54 having 35 n-Al_{0.9}GaAs/n-Al_{0.2}GaAs layer pairs, lower cladding layer 56, QW active layer structure 58, upper cladding layer 60 and upper DBR mirror 62 having 25 p-Al_{0.9}GaAs/p-Al_{0.2}GaAs layer pairs is formed on the n-GaAs substrate 51 by using a MOCVD technique. In this step, one of the AlGaAs layers of the upper DBR mirror 62 in the vicinity of the QW active layer structure 58 is replaced by the P-AlAs layer 64.

Subsequently, as shown in FIG. 4B, the second laser section 53 including the lower DBR mirror 66 having 30 undoped Al_{0.9}GaAs/Al_{0.2}GaAs layer pairs, the lower cladding layer 68, the GaInNAs-based QW active layer structure 70, the upper cladding layer 72, and the second upper DBR mirror 74 having 25 Al_{0.9}GaAs/Al_{0.2}GaAs layer pairs is consecutively formed on the first laser section 52 by using a MOCVD technique.

Thereafter, as shown in FIG. 4C, the first laser section 52 and the second laser section 53 except for a bottom part of the upper DBR mirror of the first laser section 52 is configured to form a cylindrical mesa post having a diameter of 40 μm by using a photolithography and a subsequent etching process. The etching process may be either a dry etching process or a chemical etching process.

Subsequently, as shown in FIG. 4D, the second laser section 53 is configured to form a cylindrical mesa structure having a diameter of 30 μm by a photolithography and a subsequent etching process.

Thereafter, the resultant wafer is subjected to oxidation process at a temperature of about 400 degrees C., thereby progressively oxidizing the Al content in the peripheral area of the AlAs layer at the side wall of the mesa post, selectively from the central area of the AlAs layer. Thus, the Al-oxidized annular area 64A having a width of 15 μm can be obtained as a current confinement structure. The area for the selective oxidation is controlled based on the time length for the oxidation.

Subsequently, a SiNx protective film is formed on the entire exposed surface of the layer structure except for the location for forming the annular p-side electrode 76, followed by selectively depositing the p-side annular electrode 76 having a width of 5 μm on the first mesa post, or the mesa post having a diameter of 40 μm. In addition, the bottom surface of the n-GaAs substrate 51 is polished to have a thickness of about 200 μm, followed by forming the n-side electrode 80 on the polished bottom surface of the n-GaAs substrate 51.

By the above process, the surface emitting laser having the first and second laser sections can be obtained, which emits laser having a wavelength of 1.3 μm.

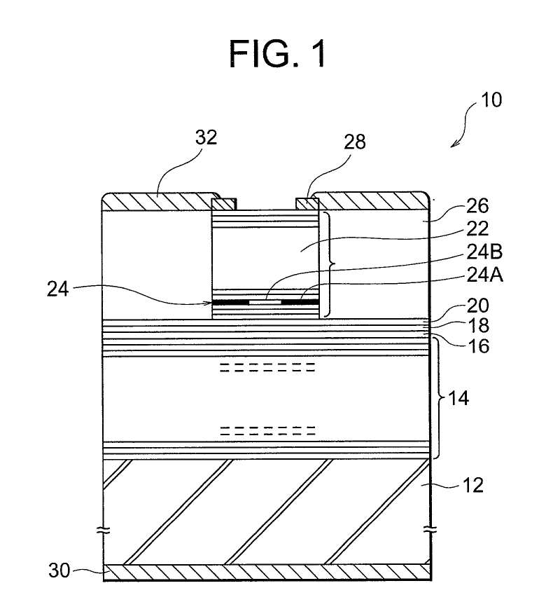

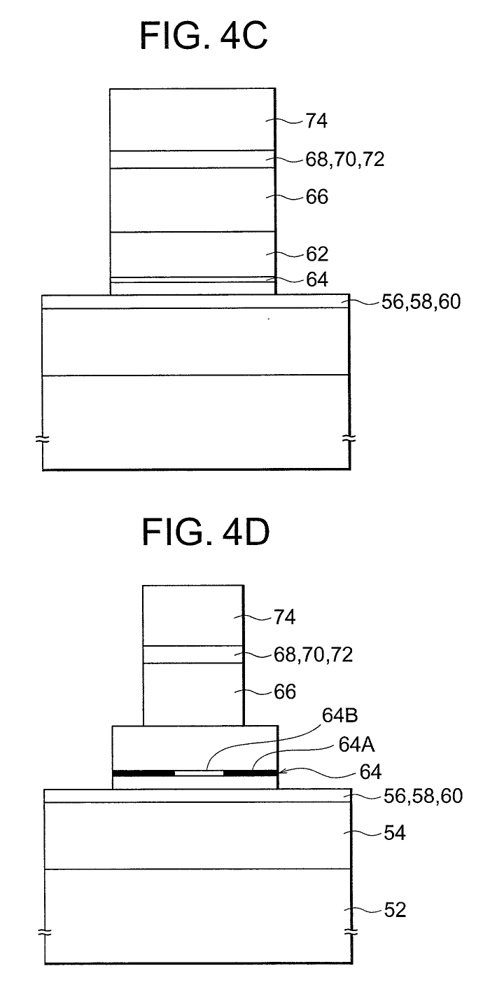

A sample of the surface emitting laser of the present embodiment was fabricated by using the above process, and subjected to measurements while the sample was driven by an auto-current-control (ACC) technique at a temperature of 85 degrees C. and an injection current of 10 mA. In addition, a comparative example of the conventional surface emitting laser of FIG. 1 was also fabricated and subjected to similar measurements. The results of the measurements are shown in FIG. 5, wherein the change rate of the output power is plotted against the elapsed time length for operation.

The curve (1) shows the results for the sample of the present embodiment, whereas the curve (2) shows the results for the comparative example. As understood from FIG. 5, the conventional laser exhibited abrupt reduction in the optical output power, whereas the sample of the embodiment exhibited substantially no change in the output power after 10,000 hours of operation. Thus, it is confirmed that the surface emitting laser of the present embodiment had improved reliability.

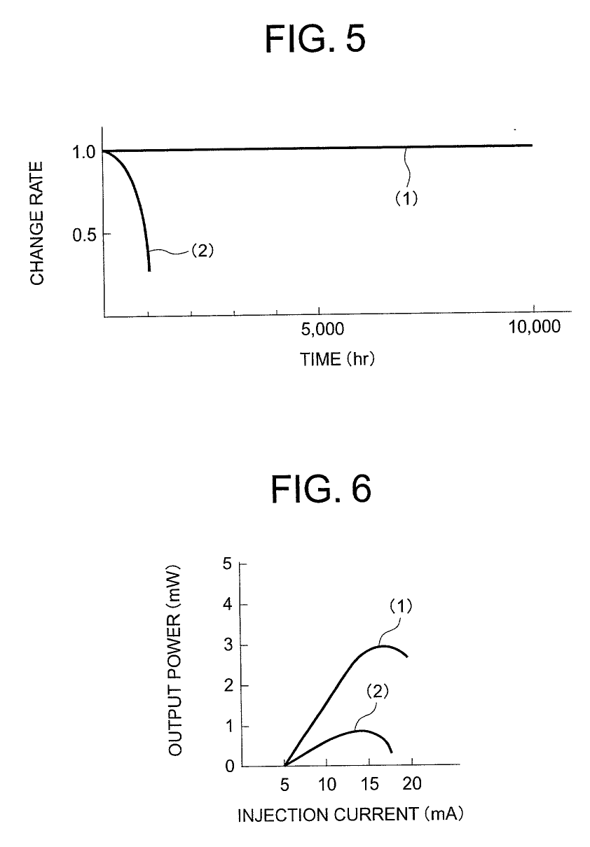

FIG. 6 shows another example of measurements for a similar sample and a similar comparative example, wherein the optical output power is plotted on ordinate against the injection current plotted on abscissa. The surface emitting laser of the present embodiment had an output power higher than the output power of the conventional laser, exhibiting a higher emission efficiency.

Further, the relation between the output power and the injection current was measured for a similar sample and a similar comparative example at different temperatures including 20 and 85 degrees C. The results are shown in FIG. 6, wherein the optical output power of the sample represented by curve (1) is significantly higher the optical output power of the comparative example represented by curve (2) for the specified injection currents.

In addition, the comparative example exhibited reduction of output power at 85 degrees C. by 1/10 compared to the output power at 20 degrees C. On the other hand, the sample of the present embodiment exhibited only a moderate reduction at 85 degrees C. by ⅔ compared to the output power at 20 degrees C.

The active layer structure of each laser section may be a bulk layer, a single QW structure or a multiple QW structure. The QW structure, if used, may have a pair of barrier layers for sandwiching therebetween a well layer.

In the surface emitting laser of the present embodiment, since no current is injected into the GaInNAs-based active layer structure 70 of the second laser section 53, the internal heat generated in the DBR mirrors 66 and 74 etc. can be reduced. This suppresses the temperature rise in the active layer structure 70 of the second laser section 53, thereby suppressing dislocations or crystal defects in the active layer structure 70 and thus increasing the lifetime of the laser.

In addition, the GaInNAs-based active layer structure has an excellent temperature characteristic. Further, the GaInNAs layer can be epitaxially grown successively from the GaAs substrate, whereby the first and second laser sections can be integrated in a monolithic structure. This allows a higher throughput of fabrication of the surface emission laser.

The well layer or absorption region of the second laser section 53 may be preferably implemented by a Ga₁₋ₓInₓN_{y}As_{1-y} layer wherein 0≦x≦0.45, and 0≦y≦0.1, or a Ga₁₋ₓInₓN_{y}Sb_{z}As_{1-y-z} layer wherein 0≦x≦0.45, 0≦y≦0.1 and 0≦z ≦0.05. For example, the QW structure may have Ga_{0.63}In_{0.37}N_{0.01}Sb_{0.016}As_{0.974}/GaAs layers. In addition, the barrier layers are not limited to GaAs layers.

A higher “x” above 0.45 in the above compositions increases the strain in the active layer to degrade the crystallinity thereof, a higher “y” above 0.1 increases crystalline defects to reduce the PL intensity., and a higher “z” above 0.05 reduces the function of the surfactant. The Sb content in the Ga₁₋ₓInₓN_{y}Sb_{z}As_{1-y-z} layer has a function as a surfactant, which suppresses a three-dimensional growth in the epitaxial process thereby allowing an excellent crystallinity to be obtained.

At least one of the DBR mirrors of the second laser section may be implemented by undoped layer pairs. The DBR mirrors of the second laser section may have a higher electric resistance because no current is injected therethrough. This allows suppression of the free carrier absorption by impurities in the DBR mirrors, whereby optical efficiency can be improved.

The present invention can be applied to lasers other than the exemplified 850-nm surface emitting laser, so long as the laser sections can be monolithically formed on a GaAs substrate and the bandgap wavelength of the first laser section is shorter than the bandgap wavelength of the second laser section. For example, if the second laser section has a bandgap wavelength of 1.2 to 1.65 μm, the bandgap wavelength of the first laser section may be selected from the wavelength range between 0.6 and 1.25 μm.

Since the above embodiments are described only for examples, the present invention is not limited to the above embodiments and various modifications or alterations can be easily made therefrom by those skilled in the art without departing from the scope of the present invention.

What is claimed is:

1. A surface emitting semiconductor laser device comprising:
a GaAs substrate;
a first laser section formed on said GaAs substrate and including a first active layer structure having a first bandgap wavelength; and
a second laser section monolithically formed on said second laser section and including a second active layer structure having a second bandgap wavelength longer than said first bandgap wavelength, said second laser section being pumped by first laser emitted by said first laser section to emit second laser.

2. The surface emitting semiconductor laser device as defined in claim 1, wherein said second active layer structure includes a quantum well (QW) structure or a bulk layer.

3. The surface emitting semiconductor laser device as defined in claim 2, wherein said QW structure includes a Ga₁₋ₓInₓN_{y}As_{1-y} well layer, given x and y being such that 0≦x≦0.45, and 0≦y≦0.1.

4. The surface emitting semiconductor laser device as defined in claim 2, wherein said QW structure includes a Ga₁₋ₓInₓN_{y}Sb_{z}As_{1-z} layer, given x, y and z being such that 0≦x≦0.45, 0≦y≦0.1 and 0≦z≦0.05.

5. The surface emitting semiconductor laser device as defined in claim 1, wherein said second laser structure includes a pair of DBR mirrors sandwiching therebetween said active layer structure, at least one of said DBR mirrors includes undoped semiconductor films.

6. The surface emitting semiconductor laser device as defined in claim 1, wherein said first bandgap wavelength resides between 0.6 and 1.25 μm, and said second bandgap wavelength resides between 1.2 and 1.65 μm.
